(19) United States
(12) Patent Application Publication
(10) Pub. No.: US 2014/0102529 A1
(43) Pub. Date: Apr. 17, 2014

(54) SOLAR CELL INTERCONNECT ASSEMBLY AND METHOD FOR MANUFACTURING THE SAME

(71) Applicants: Cory Tourino, Edgewood, NM (US); Arthur Cornfeld, Sandia Park, NM (US); Pravin Patel, Albuquerque, NM (US); Andreea Boca, Albuquerque, NM (US)

(72) Inventors: Cory Tourino, Edgewood, NM (US); Arthur Cornfeld, Sandia Park, NM (US); Pravin Patel, Albuquerque, NM (US); Andreea Boca, Albuquerque, NM (US)

(73) Assignee: Emcore Solar Power, Inc., Albuquerque, NM (US)

(21) Appl. No.: 13/741,070

(22) Filed: Jan. 14, 2013

Related U.S. Application Data
(60) Provisional application No. 61/714,844, filed on Oct. 17, 2012.

(51) Int. Cl. H01L 31/02

(52) U.S. Cl. CPC H01L 31/02008
USPC 136/256; 438/64

(57) ABSTRACT

A solar cell interconnect assembly and a method for manufacturing the same are provided. In an embodiment, the method may include: providing a solar cell having an interconnect member formed thereon, the interconnect member comprising a metallic part formed on a surface of the solar cell and a first precursor layer formed over the metallic part; providing an interconnector comprising a second precursor layer at a surface thereof; heating the interconnector and the interconnect member to a temperature equal to or above a eutectic temperature of the materials of the first and second precursor layers and pressing one of them against the other so as to form a eutectic liquid phase; and isothermal solidifying the eutectic liquid to form a bonding layer of eutectic alloy.

### REFERENCE TO RELATED APPLICATIONS

The present nonprovisional patent application claims priority under 35 U.S.C. §119(e) from U.S. Provisional patent application having Ser. No. 61/714,844, filed on Oct. 17, 2012.

### GOVERNMENT RIGHTS STATEMENT

This invention was made with government support under Contract No. FA9453-04-2-0041 awarded by the U.S. Air Force. The Government has certain rights in the invention.

### BACKGROUND OF THE INVENTION

1. Field of the Invention

The present invention relates to solar cell assembly using interconnects and method for manufacturing the same.

2. Description of the Related Art

Solder bonding an interconnect (IC) to a solar cell for aerospace applications (hereinafter, referred as space-grade solar cell), is historically a common and well known process. However, as requirements for the life expectancy of aerospace craft is increased, it was found that the solder joints connecting the IC to the solar cell were subject to fatiguing and failure in orbit. This ultimately led to the development of a parallel gap welding process which is a current, industry standard process used today.

While such a parallel gap welding process is accepted as the “Process of Record” (POR) by most members of the space community involved with solar cell integration, it is also perceived as marginally unreliable process with potential reliability risk as well.

Thus, there is need for a more robust IC connection process.

### SUMMARY

According to an aspect of the present disclosure, there is provided a solar cell assembly, comprising: a solar cell having an interconnect member formed thereon; an interconnector; and a bonding layer of eutectic alloy between the interconnector and the interconnect member for bonding the interconnector and the interconnect member.

In an embodiment, the interconnect member comprises a metallic part on the solar cell and a germanium (Ge) layer over the metallic part, and the interconnector comprises a first gold (Au) layer at a surface thereof, and the bonding layer is a layer of eutectic Au—Ge alloy which is formed from at least a portion of the first gold layer and at least a portion of the germanium layer.

In another embodiment, the interconnect member further comprises a second gold layer over the germanium layer, and wherein the bonding layer is a layer of eutectic Au—Ge alloy which is formed from at least a portion of the first gold layer, at least a portion of the second gold layer, and at least a portion of the germanium layer.

According to another aspect of the present disclosure, there is provided a method for manufacturing a solar cell assembly, comprising: providing a solar cell having an interconnect member formed thereon, the interconnect member comprising a metallic part formed on a surface of the solar cell and a first precursor layer formed over the metallic part; providing an interconnector comprising a second precursor layer at a surface thereof; heating the interconnector and the interconnect member a temperature equal to or above a eutectic temperature of the materials of the first and second precursor layers and pressing one of them against the other so that at least a portion of the first precursor layer and at least a portion of the second precursor layer form a eutectic liquid phase; and isothermal solidifying the eutectic liquid to form a bonding layer of eutectic alloy.

In an embodiment, the first precursor layer is a germanium layer; the second precursor layer is a first gold layer; the eutectic liquid phase is an Au—Ge liquid phase; and the bonding layer is a bonding layer of eutectic Au—Ge alloy.

In another embodiment, said providing of the solar cell further comprises forming a third precursor layer, which comprises the same material of the second precursor layer, over the first precursor layer, and said heating and pressing cause that at least a portion of the second precursor layer, at least a portion of the third precursor layer, and at least a portion of the first precursor layer form a eutectic liquid phase.

Further aspects, features and advantages of the present invention will be understood from the following description with reference to the drawings.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a schematic sectional view illustrating an example of method for manufacturing a solar cell assembly according to an embodiment of the present disclosure.

FIG. 2 is a schematic sectional view illustrating an example of a solar cell assembly according to an embodiment of the present disclosure.

### DESCRIPTION OF THE EMBODIMENTS

Embodiments of the present disclosure will be described in detail below with reference to the drawings. Note that similar reference numerals are used to refer to similar elements throughout the drawings, and thus repetitive descriptions thereof are omitted.

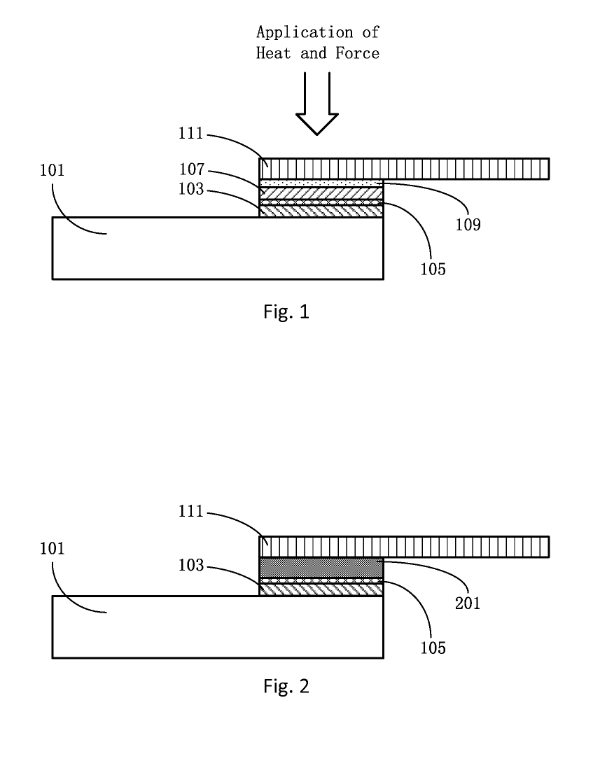

FIG. 1 is a schematic sectional view illustrating an example of method for manufacturing a solar cell assembly according to an embodiment of the present disclosure.

As shown, a solar cell 101 is provided, and the solar cell has an interconnect member formed on a surface of the solar cell 101. As mentioned above, the solar cell 101 preferably is a space-grade solar cell.

In an embodiment, the interconnect member may include a metallic part 103 formed on the solar cell and a first precursor layer 107 formed over the interconnect member 103. The interconnect member 103 can be a bonding pad or an electrode, and may include silver (Ag) as its main component. The first precursor layer 107 can be comprised of germanium (Ge); however, the present invention is not limited thereto.

It is preferable in some embodiments to provide a barrier layer 105 between the first precursor layer 107 (e.g., Ge layer) and the interconnect member 103, for suppressing or avoiding diffusion of the elements (e.g., Ag) from the interconnect pad 103 into the first precursor layer and the resultant bonding layer from the precursor layer. Typically, the barrier layer 105 can be formed of titanium (Ti), palladium (Pd), or the like). By way of example, the germanium layer can be formed by depositing germanium material onto the solar cell having the metallic part (e.g., pad or electrode) formed thereon, and patterning the deposited germanium material to leave the germanium layer over the interconnect member remained. As to other suitable materials for the first precursor layer, those skilled would readily understand suitable forming methods thereof known in the art.

An interconnector is provided on which a second precursor layer 109 was formed. In an embodiment, the interconnector can comprises a body portion and the second precursor layer 109 on the body portion. In other words, the interconnector can comprise the second precursor layer 109 at a surface thereof. The body portion can be formed of Kovar™ material, or more generally, of molybdenum, a nickel-cobalt ferrous alloy material, or a nickel iron alloy material.

The second precursor layer 109 can comprise gold (Au). As the method for forming the second precursor layer 109 on the body portion of the interconnector, various methods can be employed, including but not be limited to, plating, electroless plating, depositing (e.g., CVD, PVD), or the like.

In another preferable embodiment, the interconnect member can further comprise a third precursor layer (not shown) formed over the first precursor layer 107, for prevent the first precursor layer from being adversely affected by the circumferential environment, for example, being oxidized. In such a case, the third precursor layer can be formed of the same material (for example, Au) as the second precursor layer. To this end, the second and the third precursor layers can be collectively illustrated by the reference number 109 in FIG. 1.

The interconnector and the interconnect member can be heated to a temperature equal to or above the eutectic temperature of the precursors while one of them is pressed against the other under a certain pressure, so that at least a portion of the first precursor layer and at least a portion of the second precursor layer can form a eutectic liquid phase. In the case where the third precursor layer is also provided, said heating and pressing cause that at least a portion of the second precursor layer, at least a portion of the third precursor layer, and at least a portion of the first precursor layer form a eutectic liquid phase.

Detailed description in principle will be given with respect the above-mentioned gold-germanium (Au—Ge) binary system by way of example. The interconnector is plated with an Au layer 109, and the interconnect member comprises a Ge layer 107 and the additional Au layer (if any). In this example, the interconnector and the interconnect member can be heated to a temperature which is slightly above the eutectic temperature for Au and Ge (about 361° C.), and the pressure can be set to a moderate pressure, e.g., around 1,760,000 pascal (Pa). One pascal is equal to one Newton per square meter, or 0.102 kilogram-force per square meter (Kgf/m²), or 0.000145 pounds per square inch (psi). Expressed in psi, the pressure can be set to around 254 psi. In this case, Au, which can be from the plating layer (i.e., the first precursor layer) of the interconnector, or from both of the plating Au layer of the interconnector and the additional Au layer of the interconnection member (i.e., both of the first and third precursors), can be diffused into the Ge layer (the first precursor layer) so as to form a Au—Ge liquid phase. That is, at least a portion of the Ge layer and at least a portion of the Au layer (the second precursor layer or both of the second and third precursor layers) form a eutectic liquid phase. At this time, the Au—Ge liquid may dissolve residual surface contamination, such as gemanium oxide. It is preferable that the respective mating surfaces of the interconnector and the interconnect member are uneven so that it facilitates the Au—Ge liquid to fill voids formed by unevenness of the mating surfaces. The diffusion of Au continues resulting in isothermal solidification of the liquid phase over time. In some embodiments, the heat and the pressure may continue to be applied during the solidification. Thus, a eutectic alloy of, in this example, Au and Ge is formed. Upon cooling, there remains no liquid phase. Ideally, there can be a continuous profile of the distributions of elements at the interfaces between the resultant eutectic alloy layer and the parent layers (Au and/or Ge layer(s)) if remained.

In another embodiment, the metallic part can be annealed, for example, at 205° C. for 60 minutes, prior to the formation of the barrier layer (e.g., Pd and/or Ti) and/or the first precursor layer (e.g., Ge layer), so that less metallic diffusion of the main component (e.g., Ag) of the pad (or, electrode) occurs at or near the electrode surface. The annealing is done prior to joining the electrode and the interconnect in order to avoid such diffusion, thereby allowing a good ohmic contact to be made.

Although the above description takes the Au—Ge binary system as example, it is apparent for those skilled in the art that the above principle can be readily applied to other precursor materials as appropriate.

FIG. 2 is a schematic sectional view illustrating an example of a solar cell assembly according to an embodiment of the present disclosure.

The eutectic alloy layer 201 formed between the interconnector and the interconnect member acts as a bonding layer to bond the interconnector and the interconnect member formed on the solar cell. As shown in FIG. 2, all the Au layer 109 and Ge layer 107 were converted into a eutectic Au—Ge alloy layer, however, it is not always the case and the present invention should not be limited thereto. As above discussed, there can be portions of the Au layer 109 and/or the Ge layer 107 remained, as required.

According to the above embodiments of the present disclosure, the interconnector can be successfully bonded to the solar cell, that is, to the interconnect part formed on the solar cell. A pull test was conducted on the solar cell assembly prepared according to an example of the embodiment of the present disclosure, it was found that the joint formed of the eutectic alloy layer, or to say, the bonding of the interconnector and the interconnect part, can withstand a tensile stress of about 14.7 N (which represents a “pull strength” of about 1.5 kgf) or greater.

According to embodiments of the present invention, the reliability of the solar cell assembly can be greatly enhanced. Unlike a soldered bond that fatigues under multiple thermal cycles due to abrasion of multiple phases, the bond according to the embodiments of the present disclosure does not exhibit multiple phases and therefore the property against fatiguing can be largely improved. Further, the eutectic alloy bonding layer (or, joint) can be formed at a relatively low temperature, for example, slightly above the eutectic of the precursor materials. This will be useful in releasing the heat budget and simplifying the process. In addition, according to some embodiments of the present disclosure, only moderate pressure is required, which leads to simple process and reduced manufacturing cost. And, the tensile strength of the bond of the interconnector and the interconnect member can be increased.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

In the claims, the word ‘comprising’ or ‘having’ does not exclude the presence of other elements or steps then those listed in a claim. The terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

It is possible to embody the solar cell assemblies and the methods for manufacturing the same of the present disclosure in various ways. The above described orders of the steps for the methods are only intended to be illustrative, and the steps of the methods of the present disclosure are not limited to the above specifically described orders unless otherwise specifically stated. Note that the embodiments of the present disclosure can be freely combined with each other without departing from the spirit and scope of the invention.

Although some specific embodiments of the present invention have been demonstrated in detail with examples, it should be understood by a person skilled in the art that the above examples are only intended to be illustrative but not to limit the scope of the present invention. It should be understood that the above embodiments can be modified without departing from the scope and spirit of the present invention which are to be defined by the attached claims.

What is claimed is:

1. A solar cell assembly, comprising:
a solar cell having an interconnect member formed thereon;
an interconnector; and
a bonding layer of eutectic alloy between the interconnector and the interconnect member for bonding the interconnector and the interconnect member.

2. The solar cell assembly according to claim 1, wherein the interconnect member comprises a metallic part on the solar cell and a germanium (Ge) layer over the metallic part, and the interconnector comprises a first gold (Au) layer at a surface thereof, and
wherein the bonding layer is a layer of eutectic Au—Ge alloy which is formed from at least a portion of the first gold layer and at least a portion of the germanium layer.

3. The solar cell assembly according to claim 2, wherein the interconnect member further comprises a second gold layer over the germanium layer, and
wherein the bonding layer is a layer of eutectic Au—Ge alloy which is formed from at least a portion of the first gold layer, at least a portion of the second gold layer, and at least a portion of the germanium layer.

4. The solar cell assembly according to claim 2, wherein the bonding layer of eutectic Au—Ge alloy is formed by:
heating the interconnector and the interconnect member to a temperature above an Au—Ge eutectic temperature and pressing one of them against the other so that at least a portion of the first gold layer and at least a portion of the germanium layer form an Au—Ge liquid phase, and
isothermal solidifying the Au—Ge liquid to form the bonding layer of eutectic Au—Ge alloy.

5. The solar cell assembly according to claim 3, wherein the bonding layer of eutectic Au—Ge alloy is formed by:
heating the interconnector and the interconnect member to a temperature equal to or above an Au—Ge eutectic temperature and pressing one of them against the other so that at least a portion of the first gold layer, at least a portion of the second gold layer, and at least a portion of the germanium layer form an Au—Ge liquid phase, and
isothermal solidifying the Au—Ge liquid to form the bonding layer of eutectic Au—Ge alloy.

6. The solar cell assembly according to claim 4, wherein the pressing is performed at a moderate pressure.

7. The solar cell assembly according to claim 1, wherein the interconnect member further comprises a barrier layer formed directly over the metallic part and between the bonding layer of eutectic alloy and the metallic part.

8. The solar cell assembly according to claim 1, wherein the bonding of the interconnect member and the interconnector by the bonding layer is capable of withstanding a tensile stress of 14 N or greater.

9. The solar cell assembly according to claim 1, wherein the solar cell assembly is adaptable to be used in aerospace applications.

10. A method for manufacturing a solar cell assembly, comprising:
providing a solar cell having an interconnect member formed thereon, the interconnect member comprising a metallic part formed on a surface of the solar cell and a first precursor layer formed over the metallic part;
providing an interconnector comprising a second precursor layer at a surface thereof;
heating the interconnector and the interconnect member to a temperature equal to or above a eutectic temperature of the materials of the first and second precursor layers and pressing one of them against the other so that at least a portion of the first precursor layer and at least a portion of the second precursor layer form a eutectic liquid phase; and
isothermal solidifying the eutectic liquid to form a bonding layer of eutectic alloy.

11. The method according to claim 10, where:
the first precursor layer is a germanium layer;
the second precursor layer is a first gold layer;
the eutectic liquid phase is an Au—Ge liquid phase; and
the bonding layer is a bonding layer of eutectic Au—Ge alloy.

12. The method according to claim 10, wherein said providing of the solar cell further comprises:
providing a solar cell having the metallic part formed thereon; and
forming the first precursor layer over the metallic part.

13. The method according to claim 10, wherein said providing of the solar cell further comprises:
providing a solar cell having the metallic part formed thereon;
forming a barrier layer over the metallic part; and
forming the first precursor layer over the barrier part.

14. The method according to claim 10, wherein said providing of the solar cell further comprises forming a third precursor layer, which comprises the same material of the second precursor layer, over the first precursor layer, and wherein said heating and pressing cause that at least a portion of the second precursor layer, at least a portion of the third precursor layer, and at least a portion of the first precursor layer form a eutectic liquid phase.

15. The method according to claim 10, wherein the pressing is performed at a moderate pressure.

16. The method according to claim 12, wherein said providing of the solar cell further comprises:
annealing the metallic part before forming of the first precursor layer.

17. The method according to claim 13, wherein said providing of the solar cell further comprises:
annealing the metallic part before forming of the barrier layer.

18. The method according to claim 10, wherein the bonding of the interconnect member and the interconnector by the bonding layer is capable of withstanding a tensile of 14 N or greater.

19. The method according to claim 10, wherein the solar cell assembly is adaptable to be used in aerospace applications.
